(19) United States
(12) Patent Application Publication
(10) Pub. No.: US 2025/0275048 A1
(43) Pub. Date: Aug. 28, 2025

(54) SYNCHRONOUS PLASMA ARC RADIATING CIRCUIT (SPARC)

(71) Applicant: Booz Allen Hamilton Inc., McLean, VA (US)

(72) Inventor: David Alfred Alexander Sittner, Colorado Springs, CO (US)

(73) Assignee: Booz Allen Hamilton Inc., McLean, VA (US)

(21) Appl. No.: 19/063,821

(22) Filed: Feb. 26, 2025

Related U.S. Application Data
(60) Provisional application No. 63/557,694, filed on Feb. 26, 2024.

(51) Int. Cl. H05H 1/10; H05H 1/48

(52) U.S. Cl. CPC H05H 1/10; H05H 1/48

(57) ABSTRACT

Embodiments relate to an electromagnetic transmitter. The transmitter includes a magnetic field generator configured to generate a uniform magnetic field in a plasma medium. The transmitter includes a plasma are generator or a plasma channel generator configured to apply a direct current voltage to a conductor within a plasma medium, wherein the plasma arc or the plasma channel rotates to generate a plasma are/channel magnetic field. The transmitter includes a magnetic flux generator configured to generate a magnetic flux in the uniform magnetic field, thereby generating a non-uniform magnetic field, wherein the non-uniform magnetic field prevents or reduces a likelihood of spiraling of the plasma arc or the plasma channel. The electromagnetic transmitter emits electromagnetic radiation in a form of the plasma arc/channel magnetic field and the complementary electric field.

### CROSS-REFERENCE TO RELATED APPLICATIONS

This patent application is related to and claims the benefit of priority to U.S. provisional patent application No. 63/557,694, filed on Feb. 26, 2024, the entire contents of which is incorporated herein by reference.

### FIELD

Embodiments relate to systems and methods of generating electromagnetic radiation via a plasma arc radiating circuit.

### BACKGROUND INFORMATION

Antennas are resonant structures that accept an input excitation signal from a waveguide or transmission line and couple that signal into the radiating mode of free space. They do this because the excitation signal couples into resonant standing wave modes of charge and current density that are the solutions to Maxwell's equations for the specific antenna geometry. These modes of charge and current density then couple into the radiating mode of free space where electric and magnetic fields propagate as plane waves. The dependence of the entire process on the geometry of the antenna causes the performance of the antenna to vary with the excitation frequency. As frequency changes, various resonant modes along the conductor of the antenna will couple into the free space radiating mode better than others while other modes may be “frozen out” if the frequency falls below the cut-off frequency of the specific mode. As the frequency decreases, the wavelength of radiating modes as well as the wavelength of the resonant modes both increase, meaning that larger and larger antenna dimensions are required to support those modes.

The requirement for large antennas to transmit low frequency signals is problematic considering that low frequencies are usually desirable due to the fact that low frequency signals will travel further with less attenuation. Therefore, the most common problem faced by any antenna design engineer is achieving lower cut-off frequencies for antennas of a given length or volume. A method of transmitting low frequencies that does not depend on physical dimensions has been one of the Holy Grails of antenna engineering.

In 1965, Westinghouse developed a device that rotated an arc of plasma in a magnetic field. The purpose of the device however was not to radiate but rather to serve as a heat distribution mechanism to prevent electrode overheating in an optical plasma lamp.

In 1967, Boeing Scientific Research Laboratories released a summary of various plasma effects observed in the semiconductor indium antimonide, including Bennett pinching.

In 2017, a paper out of UCLA presented a method of radiating ultra low frequency (ULF) by mechanically rotating an array of permanent rare earth dipole magnets. Unlike that method, SPARC requires no motors or mechanical elements, nor does it require permanent magnets. SPARC operates more like an electrically rotated electromagnet.

Conventional arc plasma devices can be appreciated from the following:
1. Betsy Ancker-Johnson. Some plasma effects in semiconductors. IEEE Transactions on Nuclear Science, 14(6): 27-39, 1967.
2. Howard C Ludwig and Leslie S Frost. High intensity radiation source. https://www.patentguru.com/U.S. Pat. No. 3,280,360A.

Previous attempts at radiating with rotating magnetic fields can be appreciated from the following:
1. Skyler Selvin, M. N. Srinivas Prasad, Yikun Huang, and Ethan Wang. Spinning magnet antenna for vlf transmitting. In 2017 IEEE International Symposium on Antennas and Propagation & USNC/URSI National Radio Science Meeting, pages 1477-1478, 2017.

### SUMMARY

An exemplary embodiment can relate to an electromagnetic transmitter, The electromagnetic transmitter can include a magnetic field generator configured to generate a uniform magnetic field in a plasma medium. The electromagnetic transmitter can include a plasma arc generator or a plasma channel generator configured to apply a direct current voltage to a conductor within a plasma medium, wherein the plasma arc or the plasma channel rotates to generate a plasma arc/channel magnetic field. The electromagnetic transmitter can include a magnetic flux generator configured to generate a magnetic flux in the uniform magnetic field, thereby generating a non-uniform magnetic field. The non-uniform magnetic field can prevent or reduce a likelihood of spiraling of the plasma arc or the plasma channel. The electromagnetic transmitter can emit electromagnetic radiation in a form of the plasma arc/channel magnetic field and the complementary electric field.

An exemplary embodiment can relate to an electromagnetic transmitter array. The electromagnetic transmitter array can include plural electromagnetic radiating circuit elements. Each electromagnetic radiating circuit element can include a stack of plural dielectric substrate layers, and a doped semiconductor layer disposed on the stack. The stack can include a spiral coil with a sub-coil. The stack can include a coupling loop.

### BRIEF DESCRIPTION OF THE DRAWINGS

Other features and advantages of the present disclosure will become more apparent upon reading the following detailed description in conjunction with the accompanying drawings, wherein like elements are designated by like numerals, and wherein:

FIG. 1 shows a block diagram of an exemplary embodiment of an electromagnetic transmitter;

FIG. 2 shows top and side view schematics of an exemplary embodiment of an electromagnetic transmitter in which the plasma medium is a gas medium;

FIG. 3 shows a schematic of an exemplary embodiment of an electromagnetic transmitter in which a non-uniform magnetic field is generated in a plasma gas medium cavity of the transmitter;

FIG. 4 shows a schematic of an exemplary embodiment of an electromagnetic transmitter in which circularly polarized radiation are generated by formation of rotating magnetic fields from a plasma gas medium cavity of the transmitter;

FIG. 5 shows schematics of an exemplary embodiment of an electromagnetic transmitter in which the plasma medium is a solid state medium, and generation of a non-uniform magnetic field by the same;

FIG. 6 shows a schematic of an exemplary embodiment of an electromagnetic transmitter in which circularly polarized radiation are generated by formation of rotating magnetic fields from a plasma solid state medium of the transmitter; and

FIG. 7 shows a schematic of an exemplary electromagnetic radiating circuit array, FIG. 7 showing radiation contributions from individual electromagnetic transmitters of the array and combined radiation from synchronized electromagnetic transmitters of the array.

### DETAILED DESCRIPTION

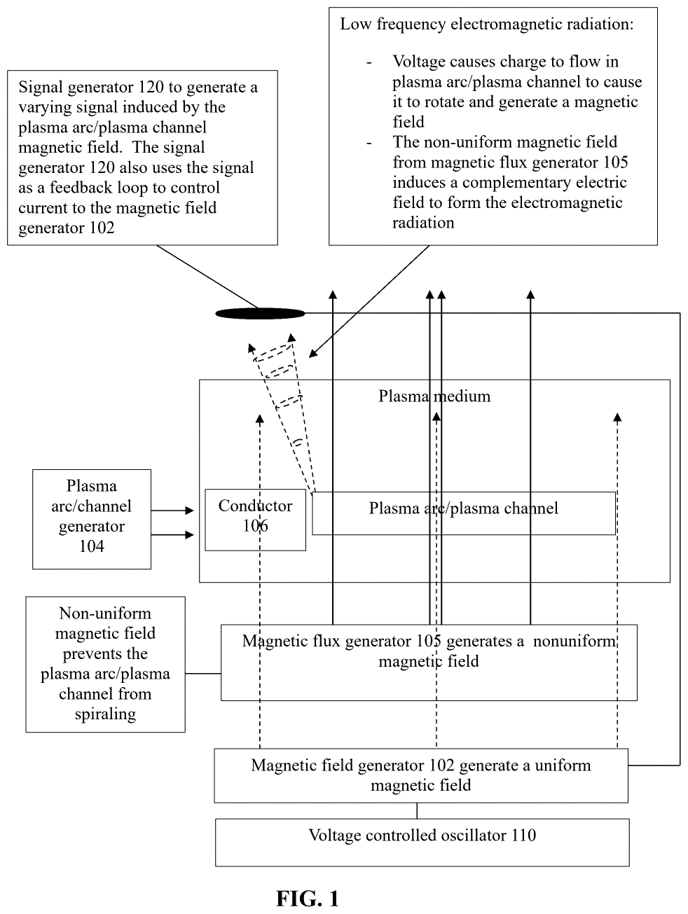

Referring to FIGS. 1, 2, and 5, an exemplary embodiment can relate to an electromagnetic transmitter 100. Embodiments of the electromagnetic transmitter 100 can be configured to generate circularly polarized radiation, which can include low frequency electromagnetic emissions (e.g., 30-300 kHz). With conventional communication systems, a transmitter-antenna generates electromagnetic emissions and a receiver-antenna receives the electromagnetic emissions, Generally, the lower the frequency of the emissions is more desirous because low frequency emissions require less energy and signal processing to transmit them over long distances. However, the size of the transmitter-antenna is inversely proportionate to the frequency of emission—i.e., the lower the frequency, the larger the transmitter-antenna is required. This poses a problem when the transmitter-antenna is intended to be used on a mobile unit or within any environment in which volume of space, weight, aerodynamics, etc. are of concern. As will be explained herein, embodiments of the innovative electromagnetic transmitter 100 can generate low frequency electromagnetic emissions without having a large footprint that otherwise would be required with conventional transmitter-antennas. The innovative electromagnetic transmitter 100 generates plasma arcs or plasma channels within a plasma medium. Structural configurations of the electromagnetic transmitter 100 cause the plasma arcs or plasma channels to rotate, forming a uniform magnetic field. Other aspects of the electromagnetic transmitter 100 generate a magnetic flux to form a non-uniform magnetic field. These operations induce an electric field that is complementary to the plasma arc/channel magnetic field—the combination of the two fields being electromagnetic radiation that emits from the electromagnetic transmitter 100. This electromagnetic radiation can be generated in the low frequency range.

The electromagnetic transmitter 100 can include a magnetic field generator 102. The magnetic field generator 102 can be configured to generate a uniform magnetic field in a plasma medium (e.g., a medium that can support the flow of both negative and positive charge carriers, which can be via a plasma z-pinching or Bennet pinching effect for example). The electromagnetic transmitter 100 can include a plasma arc generator 104 or a plasma channel generator 104. The plasma are generator 104 or a plasma channel generator 104 can be configured to apply a direct current voltage to a conductor 106 within the plasma medium, thereby generating the plasma arc(s)/plasma channel(s) within the plasma medium. The plasma arc(s)/plasma channel(s) are paths or flows of charge carriers (both positive and negative) formed in the plasma medium. As the charge flows through the plasma medium, the plasma arc(s)/plasma channel(s) experience(s) a force causing it/them to rotate. This rotation of the plasma arc(s)/plasma channel(s) within the plasma medium generates a magnetic field in the plasma medium. This magnetic field can be referred to as a plasma arc/channel magnetic field, and the plasma arc/channel magnetic field is a uniform magnetic field.

The electromagnetic transmitter 100 can include a magnetic flux generator 105, The magnetic flux generator 105 can be configured to generate a magnetic flux in the uniform magnetic field, thereby generating a spatially non-uniform magnetic field, The plasma arc(s)/plasma channel(s) can have a tendency to spiral within the plasma medium. This can be an undesirous effect. Thus, the non-uniform magnetic field can prevent or reduce a likelihood of spiraling of the plasma arc(s)/plasma channel(s).

The electromagnetic transmitter 100 can include a plasma medium. For instance, some embodiments of the electromagnetic transmitter 100 come equipped with the plasma medium while some are configured to receive the plasma medium but are not already equipped with the plasma medium. The plasma medium can be a gas medium, a solid state medium, etc. The gas medium can include argon gas, helium gas, hydrogen gas, etc. For a gas medium, the plasma arc(s)/plasma channel(s) is/are generated by an electric arc passing through the plasma medium as direct current voltage is applied to the conductor 106 within the plasma medium. As the electric are passes through the plasma medium, the temperature of the gas is raised and the gas becomes ionized. This ionization facilitates plasma formation of free-flow positive and negative charge carriers, The solid state medium can include a semiconductor material (e.g., doped GaAs, doped GaN, doped, SiC, doped InSb, etc.) having a proportion balance between hole-charges and electron-charges, For a solid state medium, doped semiconductors, in general, are designed to support both positive (e.g., holes) and negative (e.g., electrons) carriers, and therefore the carrier flow in such material facilitates plasma formation of free-flow positive and negative charge carriers. The plasma arc(s)/plasma channel(s) is/are generated by application of direct current voltage to a conductor 106 portion of the doped semiconductor so as to form a path or flow of charge carriers in the semiconductor material.

The magnetic field generator 102 in which the plasma medium is a gas medium can be a direct current driven solenoid 102. For instance, the electromagnetic transmitter 100 can include a housing 208 configured to contain the gas medium within a cavity 210. The housing 208 can have a coil 212 wound (e.g., in a helical manner) about its exterior, forming a solenoid structure. The coil 212 can be placed into contact with a direct current source 214 (e.g., a circuit having a voltage source and a resistor), Electric current applied to the coil 212 can generate a magnetic field within the volume of space defined by the coil 212—i.e., within the cavity 210 of the housing 208 since the coil 212 is wound about the housing 208.

The magnetic field generator 102 in which the plasma medium is a solid state medium can be a spiral coil 102. For instance, the electromagnetic transmitter 100 can include a doped semiconductor layer 509 disposed on a stack of dielectric substrate layers 511, wherein a spiral coil 102 is located within the stack 511. The spiral coil 102 can be placed into contact with a direct current source 214. Electric current applied to the spiral coil 102 can generate a magnetic field within the volume of space defined by the doped semiconductor layer 509 and/or the stack 511.

The plasma are generator 104 or the plasma channel generator 104 in which the plasma medium is a gas medium can be a direct current voltage source 104 (e.g., a two-terminal device that maintains a fixed voltage drop across its terminals). For instance, the electromagnetic transmitter 100 can include a housing 208 configured to contain the gas medium within a cavity 210 and a conductor 106 placed within the cavity 210. The housing 208 can further include plural electrodes 228 (e.g., two electrodes 228 spaced apart within the cavity 210 and within the gas plasma medium). The conductor 106 can be placed into contact with the direct current voltage source 104. Voltage applied to the conductor 106 causes electric current to flow through the conductor 106 and generate a plasma arc(s)/plasma channel(s) in the plasma medium that is between the two electrodes 228,

The plasma arc generator 104 or the plasma channel generator 104 in which the plasma medium is a solid state medium can be a direct current voltage source 104. For instance, the electromagnetic transmitter 100 can include a doped semiconductor layer 509 disposed on a stack of dielectric substrate layers 511. A conductor 106 portion of the doped semiconductor layer 509 can be in contact with the direct current voltage source 104. Voltage applied to the conductor 106 portion generates a plasma arc(s)/plasma channel(s) in the plasma medium of the doped semiconductor layer 509.

The magnetic flux generator 105 in which the plasma medium is a gas medium can be a radially tapered ferromagnetic material 105. The ferromagnetic material 105 can be placed within the cavity 210. The magnetic permeability of the ferromagnetic material 105 causes a magnetic flux, which produces a spatially non-uniform magnetic field within the cavity 210.

The magnetic flux generator 105 in which the plasma medium is a solid state medium can be a sub-coil 105 of reverse polarity, For instance, the spiral coil 102 can include a smaller sub-coil 105 extending therefrom or in electrical connection thereto in a reverse polarity connection. This reverse polarity connection can generate a magnetic flux, which produces a spatially non-uniform magnetic field within the volume of space defined by the doped semiconductor layer 509 and/or the stack 511.

The electromagnetic transmitter 100 can include a phase and frequency locking unit 120. The phase and frequency locking unit 120 can be configured to lock phases and frequencies of electromagnetic radiation emissions from the electromagnetic transmitter 100. The phase and frequency locking unit 120 in which the plasma medium is a gas medium can be a coupling loop 220. For instance, a metal wired formed into a coupling loop 220 can be positioned adjacent the cavity 210 so as to be within the non-uniform magnetic field, or at least be influenced by the non-uniform magnetic field. This non-uniform magnetic field can be a time varying magnetic field, and can cause the coupling loop 220 to generate a time varying voltage signal—e.g., the time varying magnetic field can induce a time varying voltage signal in the coupling loop 220. This time varying voltage signal can be used as feedback to the direct current source 214 driving the solenoid 102 to control the current being supplied to the coil 212 of the solenoid 102 so that the signal conditions a phase locked loop—i.e., the frequency and the phase of the electromagnetic radiation emitting from the transmitter 100 are kept consistent.

The phase and frequency locking unit 102 in which the plasma medium is a solid state medium can a coupling loop embedded in the stack 511. Being located with the stack 511, it is within the non-uniform magnetic field (e.g., time varying magnetic field), whereby the non-uniform magnetic field can induce a time varying voltage signal in the coupling loop. This time varying voltage signal can be used as feedback to the direct current source 214 driving the magnetic field generator 102 of the solid state transmitter 100 to control the current being supplied to the spiral coil 102 so that the signal conditions a phase locked loop—i.e., the frequency and the phase of the electromagnetic radiation emitting from the transmitter 100 are kept consistent.

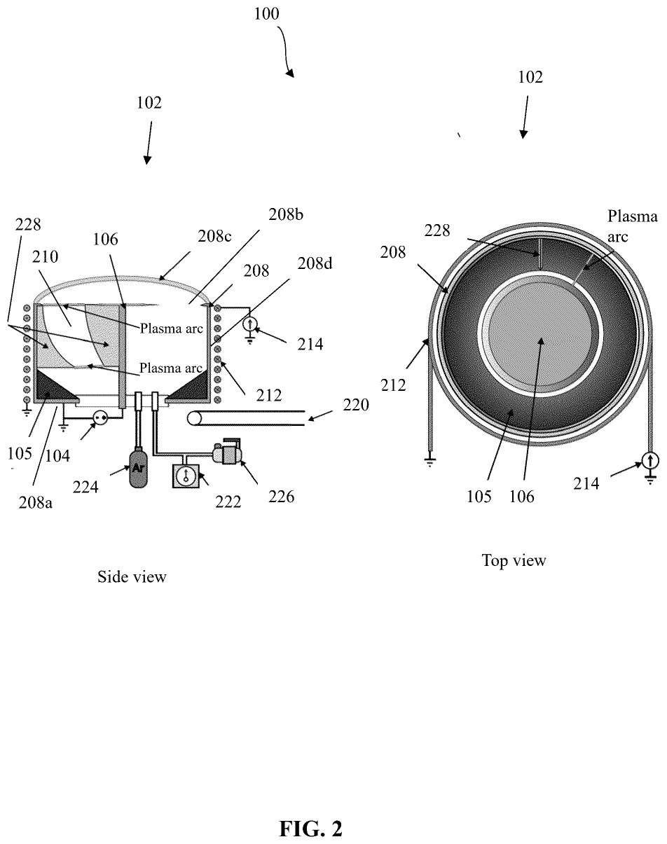

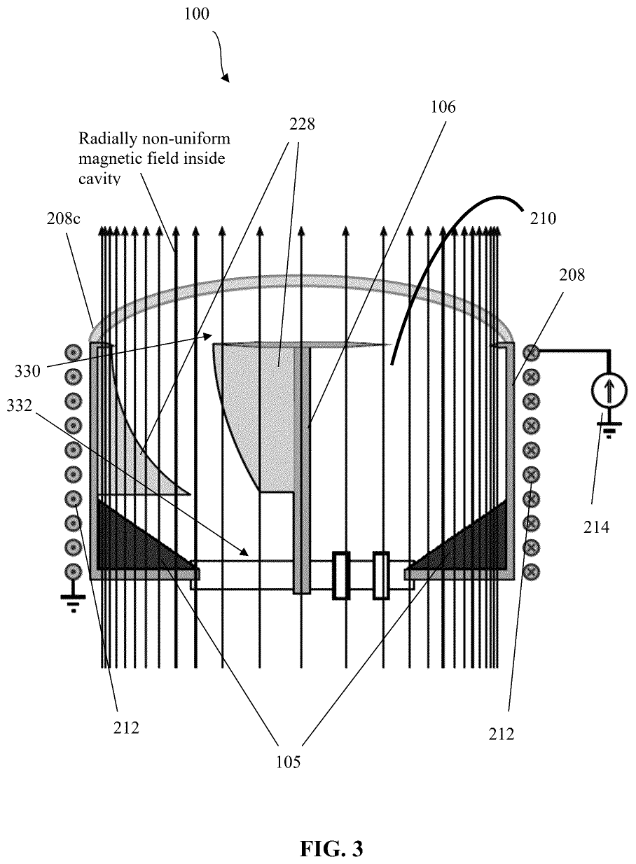

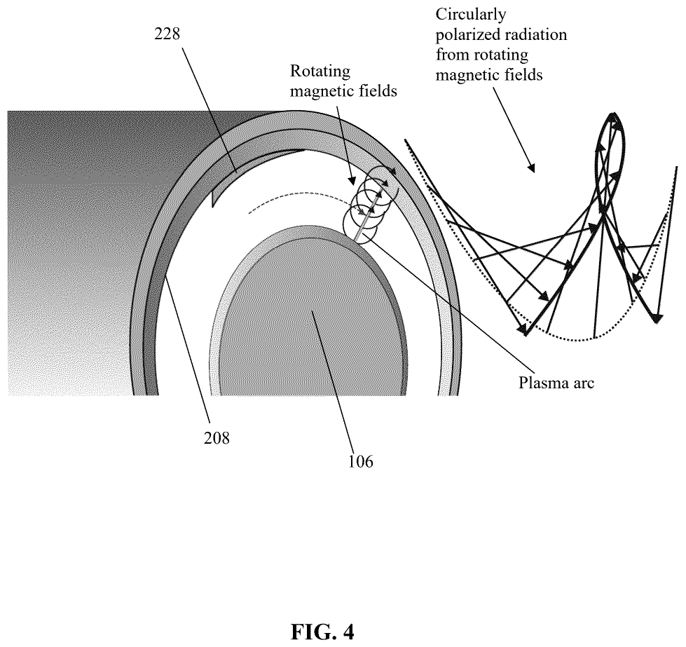

As noted herein, embodiments of the electromagnetic transmitter 100 can be used with a gas plasma medium. An exemplary transmitter 100 with for this embodiment can be appreciated from FIGS. 2-4. The transmitter 100 can include a housing 208, The housing 208 can be made of a rigid material that supports the other elements described herein but also does not interfere with the magnetic and electric fields being generated. The housing 208 can be configured to contain a gas plasma within a cavity 210 formed by the housing 208. The housing 208 can have a closed bottom 208a, an open top 208b, a dome cover 208c, and cylindrical shaped sidewalls 208d, the combination of which form an interior cavity 210. The housing 208 can include an inlet, coupling(s), valve(s), pressure sensor(s) 222, etc. to facilitate gas flow from a gas supply 224 (e.g., a gas tank) to the cavity 210 and monitor gas conditions within the cavity 210. These can be located at the closed bottom 208a. The gas supply 224 can be a gas tank containing gas under pressure and control of the valve(s) can allow flow of gas into the cavity 210 and prevent gas from flowing out from the cavity 210. Alternatively, the gas supply 224 can be connected to a pump 226, which generates the pressure to force gas flow.

The housing 208 can support one or more conductors 106 (e.g., made of electrically conducting material) located within the cavity 210. It is contemplated for there to be one conductor 106. The conductor 106 can be an elongate member extending from the closed bottom 208a to the open top 208b—e.g., the elongate member can run parallel to a longitudinal axis of the housing 208, It is contemplated for the conductor 106 to be located at a center of the cavity 210. Thus, the elongate member can be coaxial with the longitudinal axis. The conductor 106 can have one or more electrodes 228 extending therefrom—e.g., extending from the conductor 106 towards a housing sidewall 208d. It is contemplated for there to be one electrode 228 extending from the conductor 106 (e.g., a first electrode 228). The housing sidewall 208d can have one or more electrodes 228 extending therefrom—e.g., extending from the sidewall 208d towards the conductor 106, It is contemplated for there to be one electrode 228 extending from the sidewall 208d (e.g., a second electrode 228). It is further contemplated for the sidewall-extending electrode 228 to be located such that it subtends the conductor-extending electrode 228. The electrodes 228 are made of electrically conducting material, but may be configured to carry or hold more capacitance than that of the conductor 106. It is contemplated for there to be a volume of space between the conductor-extending electrode 228 (e.g., first electrode 228) and the sidewall-extending electrode 228 (e.g., second electrode 228) so as to allow a plasma arc(s)/plasma channel(s) to form between the two electrodes 228. For instance, in operation gas will be introduced into the cavity 210 and electric current will be supplied to the conductor 106, which will facilitate ionization of the gas and generation of plasma are(s)/plasma channel(s) between the two electrodes 228. It is contemplated for each electrode 228 to be in a blade-electrode (e.g., each being a planar crescent-shaped member). It is understood that this blade shape is exemplary and that other shapes, formations, numbers of electrodes 228, placement of electrodes 228, etc. can be used.

A direct current voltage source 104 can be placed into electrical contact with the conductor 106. For instance, the closed bottom 208a of the housing 208 can have a contact facilitating electrical coupling between the direct current voltage source 104 and the conductor 106. It is contemplated for the direct current voltage source 104 to be a high voltage source.

The cavity 210 can include ferromagnetic material 105. The ferromagnetic material 105 can be disposed on an inner surface of the housing 208. The ferromagnetic material 105 can be in the form of an annular structure and placed at an inner surface of the closed bottom 208a and sidewall 208d. For instance, the housing 208 can have a flat bottom 208a with cylindrical sidewalls 208d, thereby forming a circular cross-section of the cavity 210 or a circular profile of the housing sidewalls 208d. The ferromagnetic material 105 can be a ring that, when placed in the housing 208, rests on the closed bottom 208a and abuts portions of the housing bottom 208a and housing sidewalls 208d. The open portion of the ring surrounds the conductor 106, or at least a portion of the conductor 106. It is contemplated for the ferromagnetic material 105 to be in the form of a tapered ring such that the ring contiguously makes contact with a portion of the sidewall 208d, a lower corner of the housing 208, and a portion of the bottom 208a, wherein ring slants in a ramp formation from the sidewall-contact point to the bottom-contact point. Thus, the ferromagnetic material 105 can be in a shape of a tapered ring that surrounds a portion of the conductor 106. It is understood that this ring formation is exemplary and that other shapes, formations, numbers of ferromagnetic materials 105, placement of ferromagnetic materials 105, etc. can be used.

The transmitter 100 can include a direct current (DC) driven solenoid 102. The DC driven solenoid can have a cavity 210, and the cavity 210 can include the conductor 106, two electrodes 228, and ferromagnetic material 105. For instance, the housing 208 can include a coil 212 wound about an outer surface of the housing sidewall 208d. This can be done to form a solenoid structure 102, For instance, an inner surface of the housing 208 can form a periphery of the cavity 210 and define a longitudinal axis for the cavity 210. The longitudinal axis can be substantially perpendicular to a direction of the coil 212, wherein the longitudinal axis can extend from the direct current driven solenoid first end 330 to the direct current driven solenoid second end 332. Each of the conductor 106, the two electrodes 228, and the ferromagnetic material 105 can be located within the cavity 210. The coil 212 can include one or more contacts to facilitate connection to a direct current source 214. It is contemplated for the coil 212 to be wound about the housing 208 in a helical manner, but other formations can be used. It is understood that this solenoid structure 102 is exemplary and that other shapes, formations, numbers of coils 212, placement of coils 212, number of direct current sources 214, etc. can be used.

The transmitter 100 can include one or more coupling loops 102. It is contemplated for there to be one coupling loop 102. The coupling loop 102 can be located outside of the cavity 210. The coupling loop 102 can be located outside of the cavity 210 and be adjacent the direct current driven solenoid first end 330. In some embodiments, the coupling loop 102 can be located outside the housing 208 and placed adjacent the housing bottom 208a. The coupling loop 102 can be placed into contact with or in communication with the direct current source 214 so that voltage signals generated therefrom can be used feedback to control current being supplied to the solenoid coil 212. This can be via an electrical feedback circuit, a processor, a processing module, etc.

Any embodiment of the transmitter 100 and/or any component of the transmitter 100 can include or be in communication with a processing module. The processing module can include one or more processors and one or more associated memories. Any of the processors disclosed herein can be part of or in communication with a machine (e.g., a computer device, a logic device, a circuit, an operating module (hardware, software, and/or firmware), etc.). The processor can be hardware (e.g., processor, integrated circuit, central processing unit, microprocessor, core processor, computer device, etc.), firmware, software, etc. configured to perform operations by execution of instructions embodied in computer program code, algorithms, program logic, control, logic, data processing program logic, artificial intelligence programming, machine learning programming, artificial neural network programming, automated reasoning programming, etc. The processor can receive, process, and/or store data.

Any of the processors disclosed herein can be a scalable processor, a parallelizable processor, a multi-thread processing processor, etc. The processor can be a computer in which the processing power is selected as a function of anticipated network traffic (e.g. data flow). The processor can include any integrated circuit or other electronic device (or collection of devices) capable of performing an operation on at least one instruction, which can include a Reduced Instruction Set Core (RISC) processor, a Complex Instruction Set Computer (CISC) microprocessor, a Microcontroller Unit (MCU), a CISC-based Central Processing Unit (CPU), a Digital Signal Processor (DSP), a Graphics Processing Unit (GPU), a Field Programmable Gate Array (FPGA), etc. The hardware of such devices may be integrated onto a single substrate (e.g., silicon “die”), or distributed among two or more substrates. Various functional aspects of the processor may be implemented solely as software or firmware associated with the processor.

The processor can include one or more processing or operating modules. A processing or operating module can be a software or firmware operating module configured to implement any of the functions disclosed herein. The processing or operating module can be embodied as software and stored in memory, the memory being operatively associated with the processor. A processing module can be embodied as a web application, a desktop application, a console application, etc.

The processor can include or be associated with a computer or machine readable medium. The computer or machine readable medium can include memory. Any of the memory discussed herein can be computer readable memory configured to store data. The memory can include a volatile or non-volatile, transitory or non-transitory memory, and be embodied as an in-memory, an active memory, a cloud memory, etc. Examples of memory can include flash memory, Random Access Memory (RAM), Read Only Memory (ROM), Programmable Read only Memory (PROM), Erasable Programmable Read only Memory (EPROM), Electronically Erasable Programmable Read only Memory (EEPROM), FLASH-EPROM, Compact Disc (CD)-ROM, Digital Optical Disc DVD), optical storage, optical medium, a carrier wave, magnetic cassettes, magnetic tape, magnetic disk storage or other magnetic storage devices, or any other medium which can be used to store the desired information and which can accessed by the processor.

The memory can be a non-transitory computer-readable medium. The term “computer-readable medium” (or “machine-readable medium”) as used herein is an extensible term that refers to any medium or any memory, that participates in providing instructions to the processor for execution, or any mechanism for storing or transmitting information in a form readable by a machine (e.g., a computer). Such a medium may store computer-executable instructions to be executed by a processing element and/or control logic, and data which is manipulated by a processing element and/or control logic, and may take many forms, including but not limited to, non-volatile medium, volatile medium, transmission media, etc. The computer or machine readable medium can be configured to store one or more instructions thereon. The instructions can be in the form of algorithms, program logic, etc. that cause the processor to execute any of the functions disclosed herein.

Embodiments of the memory can include a processor module and other circuitry to allow for the transfer of data to and from the memory, which can include to and from other components of a communication system. This transfer can be via hardwire or wireless transmission. The communication system can include transceivers, which can be used in combination with switches, receivers, transmitters, routers, gateways, wave-guides, etc. to facilitate communications via a communication approach or protocol for controlled and coordinated signal transmission and processing to any other component or combination of components of the communication system. The transmission can be via a communication link. The communication link can be electronic-based, optical-based, opto-electronic-based, quantum-based, etc. Communications can be via Bluetooth, near field communications, cellular communications, telemetry communications, Internet communications, etc.

Transmission of data and signals can be via transmission media. Transmission media can include coaxial cables, copper wire, fiber optics, etc. Transmission media can also take the form of acoustic or light waves, such as those generated during radio-wave and infrared data communications, or other form of propagated signals (e.g., carrier waves, digital signals, etc.).

Any of the processors can be in communication with other processors of other transmitters 100, other components of a transmitter 100, or other processors of a computer device, a computer system, etc. Any of the processors can have transceivers or other communication devices/circuitry to facilitate transmission and reception of wireless signals. Any of the processors can include an Application Programming Interface (API) as a software intermediary that allows two or more applications to talk to each other. Use of an API can allow software of one processor to communicate with software of another processor.

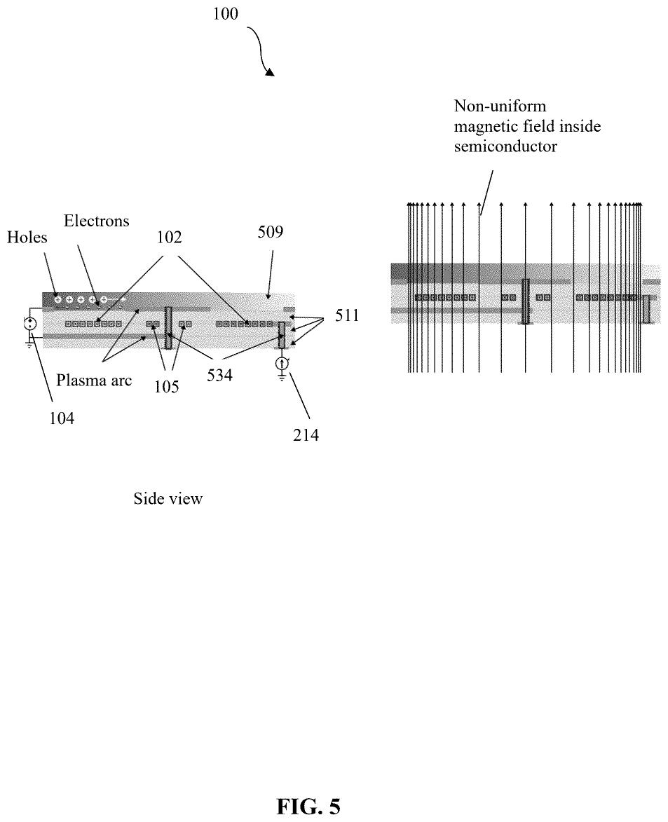

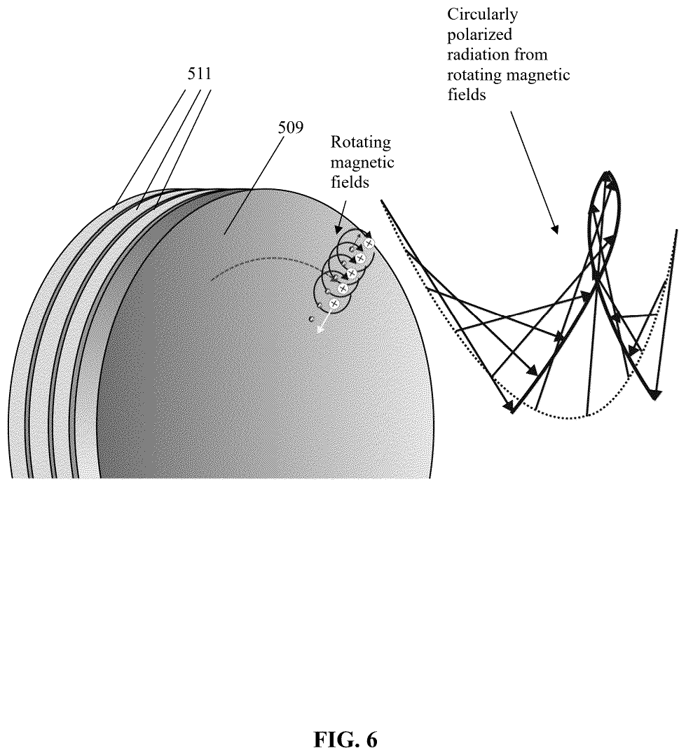

As noted herein, embodiments of the electromagnetic transmitter 100 can be used with a solid state plasma medium. An exemplary transmitter 100 with for this embodiment can be appreciated from FIGS. 5-6. The transmitter 100 can include one or more dielectric substrate layers 511, It is contemplated for there to be plural dielectric layers 511. Any one dielectric layer 511 can be the same as or different from another dielectric layer 511, in terms of material composition, thickness, dielectric properties, etc. The plural dielectric layers 511 can be arranged in a stack 511 formation. Forming one dielectric layer 511 on another can be done using known dielectric board lamination techniques with thermal set film adhesives, The stack 511 can form the base upon which one or more doped semiconductor layers 208 is/are formed. It is contemplated for there to be one doped semiconductor layer 208. The semiconductor layer can be formed on the stack 511 using known material deposition techniques, and doping can be done using known doping techniques. The doped semiconductor layer 509 can be doped GaAs, doped GaN, doped, SiC, doped InSb, etc., and doped such as to have a proportion balance between hole-charges and electron-charges. The dielectric stack-doped semiconductor structure can include a first dielectric substrate layer 511 as the bottom layer, at least one additional dielectric substrate layer 511 formed on top of the first dielectric substrate layer 551 as an intermediate dielectric substrate layer(s) 511, and a semiconductor layer 509 formed on top of the intermediate dielectric substrate layer(s) 511.

One or more holes or vias 534 can be formed in the transmitter 100. The via(s) 534 can be lined with a conductor material and be formed using known techniques (e.g., electroplating, etc.). The via(s) can be connected to ground, voltage source(s), current source(s), etc. In an exemplary embodiment, the transmitter 100 has two vias 534, A first via 534 is formed so as to extend from the semiconductor layer 509 to the first dielectric substrate layer 511. This can include extending from a bottom surface of the semiconductor layer 509, through the intermediate dielectric substrate layer(s) 511, and terminating at a bottom surface of the first dielectric substrate layer 511 or extending all the way through the first dielectric substrate layer 511. The second via 534 is formed so as to extend from an intermediate dielectric substrate layer(s) 511 to the first dielectric substrate layer 511. This can include extending from the intermediate dielectric substrate layer(s) 511 and terminating at a bottom surface of the first dielectric substrate layer 511 or extending all the way through the first dielectric substrate layer 511. The via(s) can be connected to ground, voltage source(s), current source(s), etc. at this terminus point of the first dielectric substrate layer 511.

In the exemplary embodiment shown in FIG. 5, the first via 534 terminates at the bottom surface of the first dielectric substrate layer 511. An electrical contact can be formed or placed on a side surface of the stack 511 and another electrical contact formed or placed on a side surface of the substrate layer 511. These contacts can be placed into contact with a direct voltage current source 212. One or more spiral coils 102 and one or more sub-coils 105 can be formed within the stack 511, and be placed into electrical contact with the first via 534. Voltage applied to the contacts via the direct voltage current source 212 can generate plasma arc(s)/plasma channel(s) between the contacts and the first via 534. The second via 534 extends through the bottom surface of the first dielectric substrate layer 511 and is placed into contact with a direct current supply 214 via a contact. One or more spiral coils 102 and one or more sub-coils 105 can be formed with the stack 511, and be placed into electrical contact with the second via 534. Electrical current supplied to the second via 534 can be directed towards the spiral coil(s) 102 and sub-coil(s) 105 connected therewith,

In the exemplary embodiment shown in FIG. 5, the stack 511 includes a first dielectric substrate layer 511, a second dielectric substrate layer 511, and a third dielectric substrate layer 511. The third dielectric substrate layer 511 is adjacent the doped semiconductor layer 509. The spiral coil(s) 102 and sub-coil(s) 105 are located in or on the second dielectric substrate layer 511. The spiral coil(s) 102 is/are placed in electrical contact with the direct current voltage source 104. The sub-coil(s) 105 is/are placed in electrical contact with the direct current voltage source 104 via a reverse polarity arrangement.

In any embodiment, the transmitter 100 can be driven analogously to a voltage controlled oscillator 110 configured to generate a periodic alternating current signal which can be used to modulate electric current on top of the direct current supplied to the transmitter 100. This modulation can be used to cause the transmitter 100 to emit frequency modulated analog signals and/or digital signals via frequency shift keying. For instance, digital information can be encoded on a carrier signal by periodically shifting the frequency of the carrier between plural discrete frequencies.

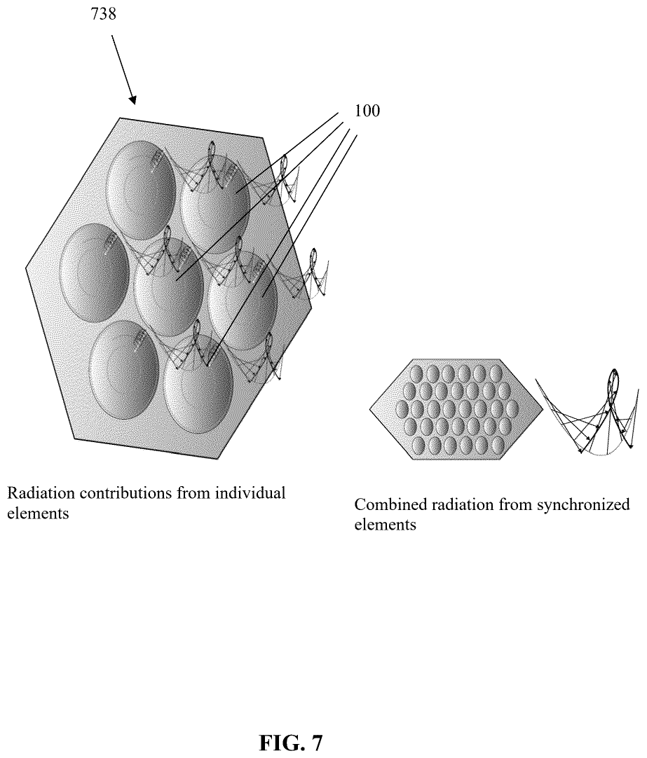

Referring to FIG. 7, an exemplary embodiment can relate to an electromagnetic transmitter array 738. The electromagnetic transmitter array 738 can include plural electromagnetic radiating circuit elements 100 (e.g., plural electromagnetic transmitters 100). Each electromagnetic radiating circuit element 100 can include a stack 511 of plural dielectric substrate layers 511, and a doped semiconductor layer 509 disposed on the stack 511. The stack 511 can include one or more spiral coils 102 with one or more sub-coils 105. Electromagnetic emissions from each transmitter 100 can be synchronized via syncing the rotation of plasma arcs/plasma channels of each transmitter 100.

### EXAMPLES

The following describes exemplary apparatuses and techniques of the systems and methods disclosed herein.

A new non-resonant method is presented for producing ultra low frequency radiation from sub-wavelength apertures, in violation of the Chu-Harrington limit, by rotating a DC magnetic field. A device is presented that accomplishes this task by taking advantage of the Bennett pinch effect in conducting plasmas. Two variations of this device are presented, one which utilizes ionic plasma in ionized argon, and another which utilizes solid state plasma in indium antimonide semiconductor.

The synchronous plasma arc radiating circuit (SPARC) produces radiation by azimuthally rotating an arc of plasma in a spatially non-uniform DC magnetic field aligned normal to the current flow. The plasma arc is established by applying a high voltage source to the center conductor. The arc appears initially inside the cavity between two blade-like electrodes connected to the center conductor and cavity wall, respectively. Due to Lorentz force effects, the arc travels up the electrode blades to the front face of the cavity. The electrode blades serve the purpose of initializing the plasma arc in a consistent location each time the high voltage source is energized.

The cavity is placed inside a solenoid driven with a DC current source. The solenoid establishes a uniform magnetic field inside the plasma cavity. The cavity is magnetically loaded with a tapered ring of high permeability ferromagnetic material to make the magnetic flux density radially non-uniform. As charge flows through the plasma arc, it experiences a force causing it to rotate around the cavity. The force experienced by charges varies proportionally with radius from the cavity center due to the non-uniform magnetic flux density which also varies proportionally with radius. The radially varying rotational force helps to keep the plasma traveling in a straight line and reduce the plasma spiraling that occurs at higher angular velocities. The spiraling of the plasma arc prevents the vector components of the rotating magnetic fields from adding coherently, limiting efficient radiation to only the lowest of low frequencies. The non-uniform magnetic field serves to overcome this limitation, so the high frequency operation of the device depends on the ability to accurately control and taper the strength of the magnetic field at the location of the plasma arc.

The current flowing through the plasma arc generates its own DC magnetic field. As the plasma arc rotates, the DC magnetic field also rotates, and its vector components experience oscillation at a frequency proportional to the angular velocity of the plasma arc. The time varying magnetic flux density induces a complementary electric field that also rotates with the plasma arc. The time-varying components of magnetic field and the induced time-varying electric field form the components of the radiated signal. The radiated mode is circularly polarized and the handedness depends on the polarity of current supplied to the solenoid. The frequency of the radiation depends on the strength of the magnetic flux density and thus, the solenoid current.

A small coupling loop of wire beneath the cavity produces a time varying voltage signal induced by the time varying magnetic field. The voltage signal conditions a phase locked loop to control the solenoid current and keep the radiation frequency and phase consistent. The device is driven analogously to a voltage controlled oscillator. By modulating the solenoid current on top of a DC bias current, the device is capable of transmitting frequency modulated analog signals and digital signals using frequency shift keying.

A tank of argon gas is used to displace all the air in the cavity with argon. An inline pressure sensor monitors the pressure of the gas in the cavity while a vacuum pump pumps the pressure of argon in the cavity to 1-10 Torr to achieve the lowest DC voltage threshold for dielectric breakdown and ionization. An air-tight glass radome keeps the argon gas inside the cavity and maintains vacuum pressures.

The principle behind SPARC works due to the filamentation effect that happens to current flowing in a plasma. Unlike conductors where the charge carriers are all electrons in the conduction band, plasmas support the flow of both negative and positive charge carriers. When an electric field in a gas is strong enough to strip electrons from their nuclei, the electrons will flow in the direction opposite the applied field while the remaining positive ions flow more slowly along the direction of the applied field, keeping the overall plasma channel electrically neutral. As charge flows through the plasma channel, Lorentz forces constrict the channel to a fine filament. This is known as plasma z-pinching or Bennett pinching. The same effect also happens in a conductor, but the lack of positive charge carriers causes the current flow to be electrically negative and the repulsive Coulomb force overpowers the attractive Lorentz force.

Another medium that supports both positive and negative charge carriers is a doped semiconductor. In fact, current flow inside a semiconductor is sometimes also referred to as a solid state plasma. In a doped semiconductor, there are free electrons in the conduction band as well as holes, or an empty space where an electron normally would be, which behave as positive charge carriers. When the proportion of free electrons and holes is balanced, the charge flow is electrically neutral and the Lorentz force causes filamentation in the semiconductor.

An extension of the SPARC device to a solid state plasma is disclosed herein. A layer of doped semiconductor lies on top of a printed circuit board stack of multiple dielectric substrate layers. Voltage is applied by a DC voltage supply and current flows in the form of holes and electrons. An embedded spiral coil on the second layer of the PCB stack produces a DC magnetic field when current flows through it from a DC current supply. The spiral coil features a small sub-coil of reversed polarity in the center which results in a radially non-uniform magnetic flux density necessary for preventing the plasma spiraling at high angular velocities. Return current flows through plated through holes to ground.

Because the fundamental operation of SPARC is not based on resonance, there is no dependence of the cut-off frequency on the dimensions of the device. The device could in theory be scaled down as far as manufacturing precision allows. There are several reasons to do this. First, as the dimensions of the device shrink, lower DC voltages are required to achieve the dielectric breakdown field strength. Second, the current flowing at the very outer edge of the plasma stream would be traveling more slowly in the azimuthal direction for any given angular velocity, so lower DC magnetic field strengths are required, and thus lower solenoid currents are required from the DC current source.

The smaller physical dimensions of the device will also limit its thermal power handling capabilities and thus limit the maximum transmitted power from a single element. A logical solution is to configure a lattice of elements to act analogously to a transmit antenna array. When the radiating elements are driven in-phase, the lower-power radiated fields from each element add coherently into a combined high power beam from the composite array. The magnetic loop coupling probe embedded into each element allows each element to be phase locked. The elements can radiate in-phase, approximating an infinite current sheet mode covering effective apertures of arbitrary dimensions. Also, depending on the frequency and the dimensions of the total composite array aperture, elements can be driven with slight phase offsets relative to each other to produce shaping and steering of radiated beam patterns.

SPARC is not an antenna. An antenna is an impedance transformer between the impedance of a transmission line and the impedance of free space. An antenna resonates with modes that are solutions to the time-symmetric Maxwell's equations, meaning that it is reciprocal, or it receives in the exact same way it transmits, and it must be driven with an excitation at the same frequency as the desired radiation. Any antenna will need an accompanying RF or microwave electronic back-end to generate the signals to be radiated.

SPARC in contrast is not reciprocal. SPARC is only capable of transmitting signals, not receiving them. Because SPARC does not operate by resonance, it is driven with simple DC power and does not require RF electronics to modulate and transmit. Also, unlike an antenna, the operating principle of SPARC prevents it from transmitting simultaneously in multiple bands. However, this limitation is overcome by the ability to use multiple independent radiating elements to create arrays of arbitrary size and shape.

Unlike an antenna, which is modulated in both amplitude and phase by a single voltage signal, SPARC is modulated in frequency by a current signal with a DC bias. Any amplitude modulation would need to be achieved by modulating the plasma current and synchronizing that modulation with the rotation of the plasma channel. SPARC is not an antenna. But it can be used like one.

It will be understood that modifications to the embodiments disclosed herein can be made to meet a particular set of design criteria. For instance, any of the components, features, or steps of apparatuses, systems, or methods disclosed herein can be any suitable number or type of each to meet a particular objective. Therefore, while certain exemplary embodiments of the apparatuses, systems, and methods disclosed herein have been discussed and illustrated, it is to be distinctly understood that the invention is not limited thereto but can be otherwise variously embodied and practiced within the scope of the following claims.

It will be appreciated that some components, features, and/or configurations can be described in connection with only one particular embodiment, but these same components, features, and/or configurations can be applied or used with many other embodiments and should be considered applicable to the other embodiments, unless stated otherwise or unless such a component, feature, and/or configuration is technically impossible to use with the other embodiments. Thus, the components, features, and/or configurations of the various embodiments can be combined in any manner and such combinations are expressly contemplated and disclosed by this statement.

It will be appreciated by those skilled in the art that the present invention can be embodied in other specific forms without departing from the spirit or essential characteristics thereof. The presently disclosed embodiments are therefore considered in all respects to be illustrative and not restrictive. The scope of the invention is indicated by the appended claims rather than the foregoing description and all changes that come within the meaning, range, and equivalence thereof are intended to be embraced therein. Additionally, the disclosure of a range of values is a disclosure of every numerical value within that range, including the end points.

What is claimed is:

1. An electromagnetic transmitter, comprising:
a magnetic field generator configured to generate a uniform magnetic field in a plasma medium;
a plasma arc generator or a plasma channel generator configured to apply a direct current voltage to a conductor within a plasma medium, wherein the plasma arc or the plasma channel rotates to generate a plasma arc/channel magnetic field;
a magnetic flux generator configured to generate a magnetic flux in the uniform magnetic field, thereby generating a non-uniform magnetic field, wherein the non-uniform magnetic field prevents or reduces a likelihood of spiraling of the plasma arc or the plasma channel
wherein the electromagnetic transmitter emits electromagnetic radiation in a form of the plasma arc/channel magnetic field and the complementary electric field.

2. The electromagnetic transmitter of claim 1 in combination with a plasma medium, wherein:
the plasma medium includes a gas medium or a solid state medium.

3. The electromagnetic transmitter of claim 2, wherein:
the plasma medium is a gas medium, the gas medium including at least one or more of argon gas, helium gas, or hydrogen gas; and
the plasma medium is a solid state medium, the solid state medium including a semiconductor material having a proportion balance between hole-charges and electron-charges.

4. The electromagnetic transmitter of claim 1, wherein:
the magnetic field generator in which the plasma medium is a gas medium is a direct current driven solenoid; and
the magnetic field generator in which the plasma medium is a solid state medium is a spiral coil.

5. The electromagnetic transmitter of claim 1, wherein:
the plasma arc generator or the plasma channel generator in which the plasma medium is a gas medium is a direct current voltage source; and
the plasma arc generator or the plasma channel generator in which the plasma medium is a solid state medium is a direct current voltage source.

6. The electromagnetic transmitter of claim 1, wherein:
the magnetic flux generator in which the plasma medium is a gas medium is a ferromagnetic material; and
the magnetic flux generator in which the plasma medium is a solid state medium is a sub-coil of reverse polarity.

7. The electromagnetic transmitter of claim 1, comprising:
a phase and frequency locking unit configured to lock phases and frequencies of electromagnetic radiation emissions from the electromagnetic transmitter.

8. The electromagnetic transmitter of claim 7, wherein:
the phase and frequency locking unit in which the plasma medium is a gas medium is a coupling loop; and
the phase and frequency locking unit in which the plasma medium is a solid state medium is a coupling loop.

9. The electromagnetic transmitter of claim 2, wherein the plasma medium is a gas medium, the electromagnetic transmitter comprising:
a direct current (DC) driven solenoid, the DC driven solenoid having a cavity, wherein the cavity includes a conductor, two electrodes, and ferromagnetic material; and
a coupling loop.

10. The electromagnetic transmitter of claim 9, comprising:
a direct current (DC) voltage supply connected to the DC driven solenoid; and
a high voltage source connected to the conductor.

11. The electromagnetic transmitter of claim 9, comprising:
a gas source configured to supply the gas medium to the cavity.

12. The electromagnetic transmitter of claim 9, wherein:
the DC driven solenoid includes a housing and a coil wound about the housing, an inner surface of the housing forming a periphery of the cavity and defining a longitudinal axis for the cavity;
each of the conductor, the two electrodes, and the ferromagnetic material is located within the cavity; and
the coupling loop is located outside the cavity.

13. The electromagnetic transmitter of claim 12, wherein:
the conductor is an elongate member that runs parallel to the longitudinal axis.

14. The electromagnetic transmitter of claim 12, wherein:
the conductor is an elongate member that is coaxial with the longitudinal axis.

15. The electromagnetic transmitter of claim 12, wherein:
the longitudinal axis is substantially perpendicular to a direction of the coil; and
the longitudinal axis extends from a DC driven solenoid first end to a DC driven solenoid second end; and
the coupling loop is located outside of the cavity and is adjacent the DC driven solenoid first end.

16. The electromagnetic transmitter of claim 12, wherein:
the ferromagnetic material is disposed on an inner surface of the housing.

17. The electromagnetic transmitter of claim 16, wherein:
the ferromagnetic material is in a shape of a tapered ring that surrounds a portion of the conductor.

18. The electromagnetic transmitter of claim 12, wherein:
the two electrodes include a first electrode extending from the conductor and a second electrode extending from the housing; and
a volume of space exists between the first electrode and the second electrode.

19. The electromagnetic transmitter of claim 12, wherein:
each of the first electrode and the second electrode is a blade-electrode.

20. The electromagnetic transmitter of claim 2, wherein the plasma medium is a solid state medium, the electromagnetic transmitter comprising:
a stack of plural dielectric substrate layers; and
a doped semiconductor layer disposed on the stack; and
wherein the stack includes a spiral coil with a sub-coil. wherein the stack includes a coupling loop.

21. The electromagnetic transmitter of claim 20, wherein:
the stack includes a first dielectric substrate layer, a second dielectric substrate layer, and a third dielectric substrate layer;
the third dielectric substrate layer is adjacent the doped semiconductor layer; and
the spiral coil is located in or on the second dielectric substrate layer.

22. The electromagnetic transmitter of claim 20, wherein:
the spiral coil is configured to be placed in electrical contact with a direct current (DC) voltage supply; and
the sub-coil is configured to be placed in electrical contact with the DC voltage supply via a reverse polarity arrangement.

23. An electromagnetic transmitter array, comprising:
plural electromagnetic radiating circuit elements, each electromagnetic radiating circuit element including:
a stack of plural dielectric substrate layers;
a doped semiconductor layer disposed on the stack; and
wherein the stack includes a spiral coil with a sub-coil.
wherein the stack includes a coupling loop.
